(19) United States
(12) Patent Application Publication
(10) Pub. No.: US 2020/0328189 A1
(43) Pub. Date: Oct. 15, 2020

(54) SEMICONDUCTOR PACKAGES INCLUDING A THERMAL CONDUCTION NETWORK STRUCTURE

(71) Applicant: SK hynix Inc., Icheon-si Gyeonggi-do (KR)

(72) Inventor: Ki Jun SUNG, Cheongju-si Chungcheongbuk-do (KR)

(73) Assignee: SK hynix Inc., Icheon-si Gyeonggi-do (KR)

(21) Appl. No.: 16/688,634

(22) Filed: Nov. 19, 2019

(30) Foreign Application Priority Data
Apr. 9, 2019 (KR) 10-2019-0041286

(51) Int. Cl. H01L 25/065

(52) U.S. Cl. CPC H01L 25/0657; H01L 2225/06513; H01L 2225/06524; H01L 2225/06589; H01L 2225/06555; H01L 2225/06582; H01L 2225/06541

(57) ABSTRACT

A semiconductor package includes a second semiconductor die stacked on a first semiconductor die, an encapsulant layer on the first semiconductor die and adjacent to the second semiconductor die, and a thermal conduction network structure including a plurality of thermal conduction balls dispersed in the encapsulant layer.

### CROSS-REFERENCE TO RELATED APPLICATIONS

The present application claims priority under 35 U.S.C 119(a) to Korean Application No. 10-2019-0041286, filed on Apr. 9, 2019, which is incorporated herein by references in its entirety.

### BACKGROUND

### 1. Technical Field

The present disclosure relates to semiconductor package technologies and, more particularly, to semiconductor packages including a thermal conduction network structure.

### 2. Related Art

Recently, a lot of effort has been focused on embedding a plurality of semiconductor dies in a single package. That is, single unified packages including a plurality of semiconductor dies designed to operate at a high speed with large data processing capacity and multi-functionality are increasingly in demand for the development of high performance electronic systems. A system-in-package (SiP) technology is attractive as a candidate for realizing single unified semiconductor packages.

SiPs having various structures have been proposed to provide high-performance unified semiconductor packages. For example, SiPs may be realized to have a three-dimensional structure including a bottom semiconductor die and a top semiconductor die stacked on the bottom semiconductor die. The three-dimensional structure of the SiPs may have a disadvantage in that heat is not efficiently dissipated due to the vertical stacking of the semiconductor dies. Accordingly, a lot of effort has been focused on improving the removal of heat from SiPs.

### SUMMARY

According to an embodiment, a semiconductor package includes a second semiconductor die stacked on a first semiconductor die, an encapsulant layer disposed on the first semiconductor die and adjacent to the second semiconductor die, and a thermal conduction network structure including a plurality of thermal conduction balls dispersed in the encapsulant layer.

According to another embodiment, a semiconductor package includes a second semiconductor die stacked on a first semiconductor die, an encapsulant layer disposed on the first semiconductor die to surround the second semiconductor die, a plurality of ball cores dispersed in the encapsulant layer, and a thermal conduction network structure surrounding surfaces of the plurality of ball cores and extending to connect the plurality of ball cores to each other.

### BRIEF DESCRIPTION OF THE DRAWINGS

FIG. 1 is a cross-sectional view illustrating a semiconductor package according to an embodiment.

FIG. 2 is a plan view illustrating an encapsulant layer of the semiconductor package shown in FIG. 1.

FIG. 3 is a cross-sectional view illustrating a thermal conduction network structure of the semiconductor package shown in FIG. 1.

FIG. 4 is a cross-sectional view illustrating a thermal conduction ball constituting the thermal conduction network structure shown in FIG. 3.

FIG. 5 is a cross-sectional view focusing on a first semiconductor die of the semiconductor package shown in FIG. 1.

FIG. 6 is a cross-sectional view focusing on a second semiconductor die stack of the semiconductor package shown in FIG. 1.

FIG. 7 is a cross-sectional view illustrating a second semiconductor die stack included in a semiconductor package according to an embodiment.

FIG. 8 is a cross-sectional view illustrating a passivation layer of a semiconductor package according to an embodiment.

FIG. 9 is a cross-sectional view illustrating a semiconductor package according to an embodiment.

FIG. 10 is a plan view illustrating an encapsulant layer of the semiconductor package shown in FIG. 9.

FIG. 11 is a cross-sectional view illustrating a thermal conduction network structure of the semiconductor package shown in FIG. 9.

FIG. 12 is a cross-sectional view illustrating a coated ball core constituting the thermal conduction network structure shown in FIG. 11.

FIG. 13 is a block diagram illustrating an electronic system employing a memory card including at least one semiconductor package according to an embodiment.

FIG. 14 is a block diagram illustrating another electronic system including at least one semiconductor package according to an embodiment.

### DETAILED DESCRIPTION OF THE EMBODIMENTS

The terms used herein may correspond to words selected in consideration of their functions in the embodiments, and the meanings of the terms may be construed to be different according to ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

It will be understood that although the terms “first,” “second,” “third” etc. may be used herein to describe various elements, these elements should not be limited by these terms. These terms are only used to distinguish one element from another element, but not used to define only the element itself or to mean a particular sequence.

It will also be understood that when an element or layer is referred to as being “on,” “over,” “below,” “under,” or “outside” another element or layer, the element or layer may be in direct contact with the other element or layer, or intervening elements or layers may be present. Other words used to describe the relationship between elements or layers should be interpreted in a like fashion (e.g., “between” versus “directly between” or “adjacent” versus “directly adjacent”).

Spatially relative terms, such as “beneath,” “below,” “lower,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other elements or features. The device may be otherwise oriented (rotated 90 degrees or at other orientations) and the spatially relative descriptors used herein interpreted accordingly.

A semiconductor package may include electronic devices such as semiconductor chips or semiconductor dies. The semiconductor chips or the semiconductor dies may be obtained by separating a semiconductor substrate such as a wafer into a plurality of pieces using a die sawing process. The semiconductor chips may correspond to memory chips, logic chips (including application specific integrated circuits (ASIC) chips), or system-on-chips (SoC). The memory chips may include dynamic random access memory (DRAM) circuits, static random access memory (SRAM) circuits, NAND-type flash memory circuits, NOR-type flash memory circuits, magnetic random access memory (MRAM) circuits, resistive random access memory (ReRAM) circuits, ferroelectric random access memory (FeRAM) circuits or phase change random access memory (PcRAM) circuits which are integrated on the semiconductor substrate. The logic chips may include logic circuits which are integrated on the semiconductor substrate. The semiconductor package may be employed in communication systems such as mobile phones, electronic systems associated with biotechnology or health care, or wearable electronic systems. The semiconductor packages may be employed in internet of things (IoT).

Same reference numerals refer to same elements throughout the specification. Even though a reference numeral is not mentioned or described with reference to a drawing, the reference numeral may be mentioned or described with reference to another drawing. In addition, even though a reference numeral is not shown in a drawing, it may be mentioned or described with reference to another drawing.

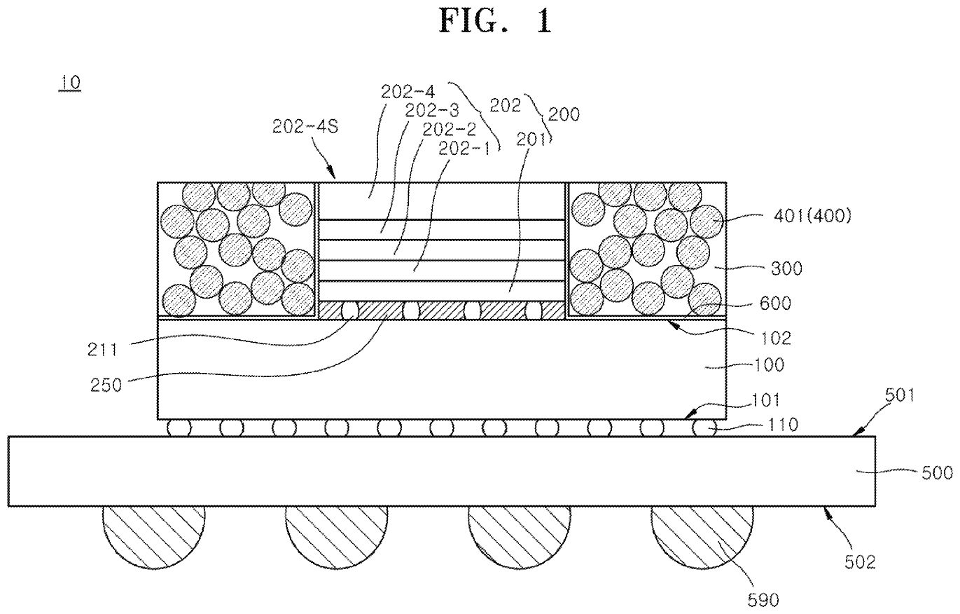

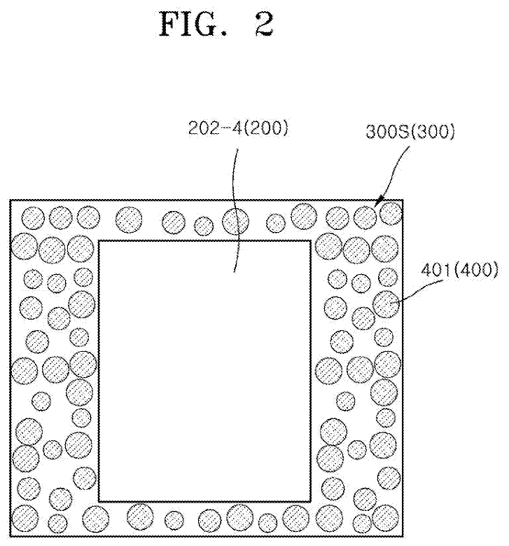

FIG. 1 is a cross-sectional view illustrating a semiconductor package 10 according to an embodiment. FIG. 2 is a plan view illustrating an encapsulant layer 300 of the semiconductor package 10 shown in FIG. 1.

Referring to FIGS. 1 and 2, the semiconductor package 10 may be configured to include a first semiconductor die 100, a second semiconductor die stack 200, the encapsulant layer 300, and a thermal conduction network structure 400. The semiconductor package 10 may further include a package substrate 500 on which the first semiconductor die 100 is mounted.

The package substrate 500 may act as an interconnection member that electrically connects the semiconductor package 10 to an external device or another module. The package substrate 500 may be, for example, a printed circuit board (PCB). The package substrate 500 may have a first surface 501 and a second surface 502 which are opposed to each other. Outer connectors 590 may be attached to the second surface 502 of the package substrate 500 which are electrically connected to an external device or another module. The outer connectors 590 may be, for example, solder balls.

The first semiconductor die 100 may be disposed on the first surface 501 of the package substrate 500. The first semiconductor die 100 may be electrically connected to the package substrate 500 through first inner connectors 110. The first inner connectors 110 may be bonded to a first surface 101 of the first semiconductor die 100. The first inner connectors 110 may be bumps or bump-shaped connectors. The first semiconductor die 100 may be a processor performing logical operations. The first semiconductor die 100 operating as a processor may be a graphic processing unit (GPU), a central processing unit (CPU), or an application specific integrated circuit (ASIC) semiconductor device.

The second semiconductor die stack 200 may be disposed on the first semiconductor die 100. The second semiconductor die stack 200 may be configured to include a plurality of semiconductor dies which are vertically stacked. For example, the second semiconductor die stack 200 may be configured to include a second semiconductor die 201 and a plurality of third semiconductor dies 202 stacked on the second semiconductor die 201.

The second semiconductor die 201 of the second semiconductor die stack 200 may be electrically connected to the first semiconductor die 100 through second inner connectors 211. The second semiconductor die 201 may be vertically stacked on the first semiconductor die 100 to overlap the first semiconductor die 100, as shown in the cross-sectional view of FIG. 1 and the plan view of FIG. 2. The first inner connectors 110 may be attached to the first surface 101 of the first semiconductor die 100, and the second inner connectors 211 may be attached to a second surface 102 of the first semiconductor die 100 opposite to the first inner connectors 110. The first inner connectors 110 may electrically connect the first semiconductor die 100 to the package substrate 500, and the second inner connectors 211 may electrically connect the second semiconductor die 201 to the first semiconductor die 100.

A first adhesive layer 250 may be disposed between the second semiconductor die 201 and the first semiconductor die 100. The first adhesive layer 250 may bond the second semiconductor die 201 to the first semiconductor die 100 and may electrically isolate the second inner connectors 211 from each other. The first adhesive layer 250 may include a non-conductive film (NCF). The first adhesive layer 250 may be an underfill layer corresponding to a dielectric layer disposed between the second semiconductor die 201 and the first semiconductor die 100.

The encapsulant layer 300 may be disposed to cover portions of the second surface 102 of the first semiconductor die 100, specifically, those portions not overlapped by the second semiconductor die stack 200. The encapsulant layer 300 may be disposed to surround side surfaces of the second semiconductor die stack 200. In some embodiments, the encapsulant layer 300 covers the top surface 202-4S of the second semiconductor die stack 200. Thus, the encapsulant layer 300 may protect the second semiconductor die stack 200 including the second semiconductor die 201. The encapsulant layer 300 may include an encapsulant material such as an epoxy molding compound (EMC) material. A plurality of thermal conduction balls 401 may be dispersed in the encapsulant layer 300.

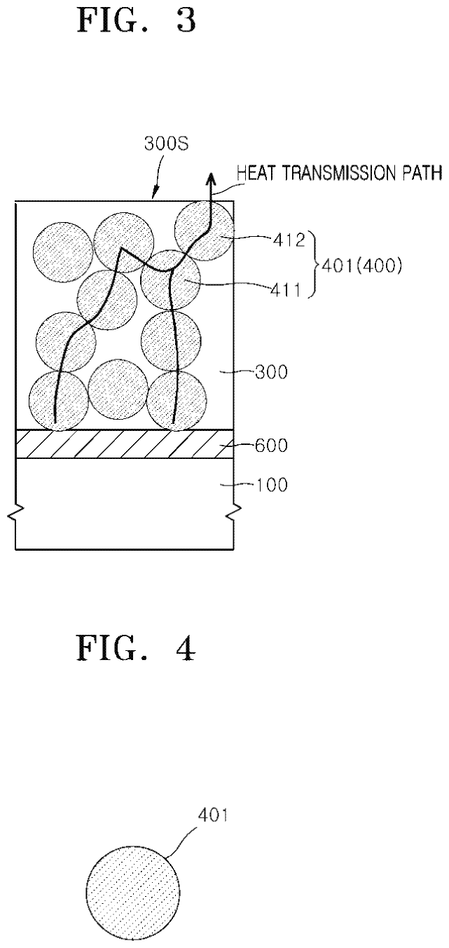

FIG. 3 is a cross-sectional view illustrating the thermal conduction network structure 400 of the semiconductor package 10 shown in FIG. 1.

Referring to FIGS. 1 and 3, the plurality of thermal conduction balls 401 may be dispersed in the encapsulant layer 300 to form the thermal conduction network structure 400. Two adjacent thermal conduction balls, labeled as a first thermal conduction ball 411 and a second thermal conduction ball 412, among the plurality of thermal conduction balls 401 are shown to be in contact with each other. Thermal conduction balls 401 not in direct contact may still be in contact with each other through intermediary thermal conduction balls 401. The plurality of thermal conduction balls 401 directly and indirectly contacting each other form thermal connections which collectively constitute the thermal conduction network structure 400.

The thermal conduction network structure 400 may provide contiguous and continuous heat conduction paths, through which heat is conducted, in the encapsulant layer 300. Some of the thermal conduction balls 401, for example, a portion of the second thermal conduction ball 412, may be exposed at a surface 300S of the encapsulant layer 300. Because the thermal conduction balls 401 are in thermal contact with each other, heat may be conducted through the thermal conduction balls 401, from one ball to the next. The thermal conduction network structure 400 including the thermal conduction balls 401 contacting each other may conduct the heat generated by the first semiconductor die 100 to the surface 300S of the encapsulant layer 300. The thermal conduction network structure 400 may provide heat transmission paths, illustrated in FIG. 3, that conduct the heat generated from the first semiconductor die 100 toward an outside region of the encapsulant layer 300.

FIG. 4 is a cross-sectional view illustrating a thermal conduction ball 401 of the thermal conduction network structure 400 shown in FIG. 3.

Referring to FIGS. 3 and 4, each of the thermal conduction balls 401 may include a thermally conductive material and may have a ball shape. The thermal conduction balls 401 may include a thermally conductive material having a thermal conductivity which is relatively higher than a thermal conductivity of the encapsulant layer 300. For example, the thermal conduction balls 401 may include metal such as copper, nickel, stainless steel (SUS) or zinc. The thermal conduction balls 401 may include a thermal conduction material such as a carbon nanotube material.

For various embodiments, the thermal conduction balls 401 are spherical in shape. The thermal conduction network structure 400 may consist of uniformly sized thermal conduction balls 401 in some embodiments. In other embodiments, thermal conduction balls 401 of mixed sizes may be included in the thermal conduction network structure 400.

In a number of embodiments, the thermal conduction balls 401 may be non-spherically shaped. For example, the thermal conduction balls 401 may be polygonal-, oval-, or disk-shaped “balls.” In different embodiments, the thermal conduction balls 401 may have any three-dimensional shape or shapes that allows the balls 401 to form connection chains that result in heat transmission paths.

For some embodiments, the thermal conduction network structure 400 includes thermal conduction balls 401 having different sizes and/or shapes. For example, the thermal conduction balls 401 may include spherical balls and oval balls 401, with the possible addition of other shapes, wherein all or some of the different shapes occurs with a distribution of different sizes.

The encapsulant material of the encapsulant layer 300 may include a dielectric material such as an epoxy resin material or may include a dielectric material containing ceramic fillers. These encapsulant materials may have a relatively low thermal conductivity as compared with a metal material and a carbon nanotube material. However, according to an embodiment, the thermal conduction network structure 400 including the thermal conduction balls 401 may conduct heat faster than the encapsulant layer 300 including the encapsulant material alone because the thermal conduction balls 401 have a relatively high thermal conductivity as compared with the encapsulant material of the encapsulant layer 300.

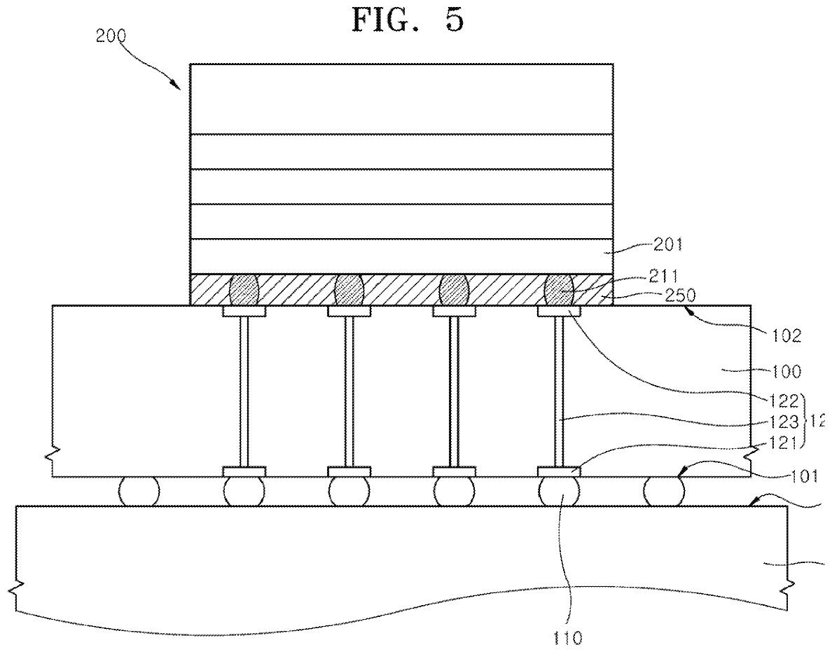

FIG. 5 is a cross-sectional view focusing on the first semiconductor die 100 of the semiconductor package 10 shown in FIG. 1.

Referring to FIG. 5, the first semiconductor die 100 may include internal connection structures 120 electrically connecting the second semiconductor die 201 to the package substrate 500. For example, each of the internal connection structures 120 may be configured to include a first connection pad 121, a second connection pad 122, and a first through via 123.

The first connection pads 121 of the internal connection structures 120 may be conductive landing potions to which the first inner connectors 110 are attached. The first connection pads 121 may be disposed on the first surface 101 of the first semiconductor die 100, which faces the first surface 501 of the package substrate 500. The first inner connectors 110 may electrically connect the first connection pads 121 to the package substrate 500.

The second connection pads 122 of the internal connection structures 120 may be conductive landing potions to which the second inner connectors 211 are attached. The second connection pads 122 may be disposed on the second surface 102 of the first semiconductor die 100, which faces the second semiconductor die 201. The second inner connectors 211 may electrically connect the second connection pads 122 to the second semiconductor die 201.

The first through vias 123 of the internal connection structures 120 may be disposed to electrically connect the first connection pads 121 to the second connection pads 122. The second semiconductor die 201 electrically coupled to the second connection pads 122 may be electrically connected to the package substrate 500 electrically coupled to the first connection pads 121 by the first through vias 123. Thus, the second semiconductor die 201, or the second semiconductor die stack 200 including the second semiconductor die 201, may be electrically connected to the package substrate 500 through the first semiconductor die 100.

The first through vias 123 may be through silicon vias (TSVs). The first through vias 123 may be disposed to substantially penetrate the first semiconductor die 100. The first through vias 123 may overlap the first connection pads 121 in a plan view and may be directly connected to the first connection pads 121. In an embodiment, extra interconnection lines (not shown) may be disposed between the first through vias 123 and the first connection pads 121 to electrically connect the first through vias 123 to the first connection pads 121.

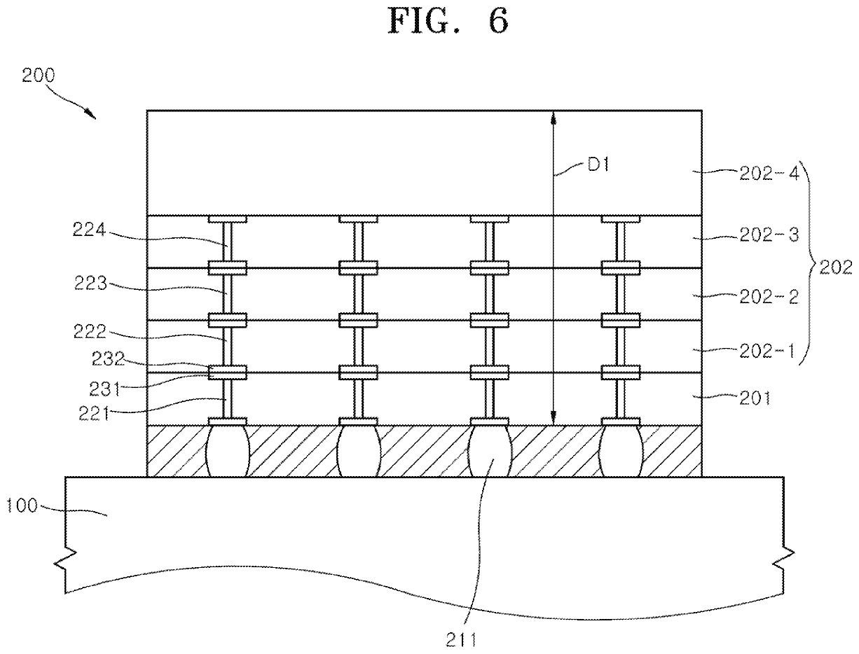

FIG. 6 is a cross-sectional view focusing on the second semiconductor die stack 200 of the semiconductor package 10 shown in FIG. 1.

Referring to FIG. 6, the second semiconductor die stack 200 may include the second semiconductor die 201 and the plurality of third semiconductor dies 202 stacked on the second semiconductor die 201. The second semiconductor die stack 200 may be a memory semiconductor device. For example, the second semiconductor die stack 200 may be a high bandwidth memory (HBM) device. In such a case, the second semiconductor die 201 of the second semiconductor die stack 200 may act as a base die of the HBM device, and the third semiconductor dies 202 of the second semiconductor die stack 200 may be core dies for HBM device.

Second through vias 221 may be disposed to substantially penetrate the second semiconductor die 201. The second through vias 221 may provide paths that electrically connect a first level die 202-1 of the third semiconductor dies 202 to the first semiconductor die 100. Third through vias 222 may be disposed to substantially penetrate the first level die 202-1 of the third semiconductor dies 202. The third through vias 222 may provide paths that electrically connect a second level die 202-2 of the third semiconductor dies 202 to the second semiconductor die 201. Fourth through vias 223 may be disposed to substantially penetrate the second level die 202-2 of the third semiconductor dies 202. The fourth through vias 223 may provide paths that electrically connect a third level die 202-3 of the third semiconductor dies 202 to the first level die 202-1 of the third semiconductor dies 202. Fifth through vias 224 may be disposed to substantially penetrate the third level die 202-3 of the third semiconductor dies 202. The fifth through vias 224 may provide paths that electrically connect a fourth level die 202-4 of the third semiconductor dies 202 to the second level die 202-2 of the third semiconductor dies 202. For the pictured embodiment, no through vias are disposed in the fourth level die 202-4 of the third semiconductor dies 202.

The first level die 202-1 located at a bottommost level among the third semiconductor dies 202 may be stacked on the second semiconductor die 201 using a direct bonding interconnection (DBI) technique. For example, the first level die 202-1 of the third semiconductor dies 202 may be disposed on the second semiconductor die 201 such that third connection pads 231 of the second semiconductor die 201 face and directly contact fourth connection pads 232 of the first level die 202-1, and the fourth connection pads 232 may be bonded to the third connection pads 231. The first level die 202-1 of the third semiconductor dies 202 may substantially be in direct contact with the second semiconductor die 201. The DBI technique may be executed by bonding a silicon surface to another silicon surface, by bonding a silicon oxide surface or a silicon nitride surface to another silicon oxide surface or another silicon nitride surface, or by bonding a metal surface such as a copper surface to another surface of the same metal.

The third semiconductor dies 202 may be vertically stacked on the second semiconductor die 201 using the DBI technique. Because the second semiconductor die 201 and the third semiconductor dies 202 directly contact each other, it might be the case that no inner connectors are used to electrically connect the second semiconductor die 201 and the third semiconductor dies 202 to each other. If the inner connectors are used to electrically connect the second semiconductor die 201 and the third semiconductor dies 202 to each other, the second and third semiconductor dies 201 and 202 may be vertically spaced apart from each other due to the presence of the inner connectors. However, according to an embodiment of the present disclosure, the second semiconductor die 201 and the third semiconductor dies 202 may be in direct contact with each other by using the DBI technique without the inner connectors. That is, the third semiconductor dies 202 may be stacked on the second semiconductor die 201 without an intervening gap.

As described above, because the third semiconductor dies 202 are stacked on the second semiconductor die 201 to have substantially no gap between the third semiconductor dies 202 and the second semiconductor die 201, a thickness D1 of the second semiconductor die stack 200 may be reduced. Accordingly, a total thickness of the semiconductor package (10 of FIG. 1) may be reduced.

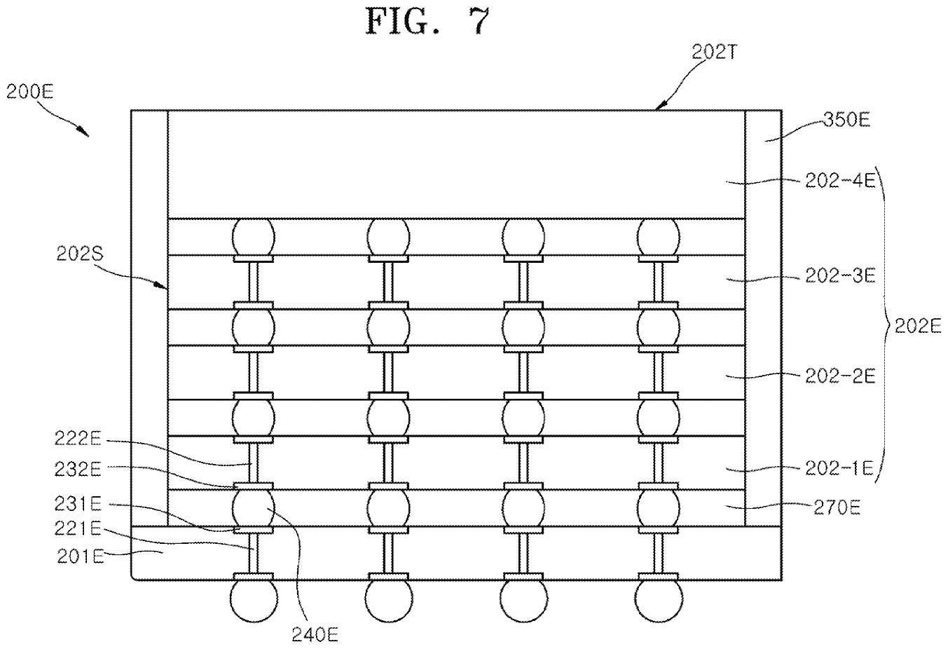

FIG. 7 is a cross-sectional view illustrating another second semiconductor die stack 200E with which the second semiconductor die stack 200 shown in FIG. 6 can be replaced.

Referring to FIG. 7, the second semiconductor die stack 200E may include a second semiconductor die 201E and a first level die 202-1E of third semiconductor dies 202E which are bonded to each other by third inner connectors 240E. The third inner connectors 240E may be disposed to electrically and mechanically connect third connection pads 231E of the second semiconductor die 201E to fourth connection pads 232E of the first level die 202-1E of the third semiconductor dies 202E. A second adhesive layer 270E may be disposed between the second semiconductor die 201E and the first level die 202-1E of the third semiconductor dies 202E to bond or attach the first level die 202-1E of the third semiconductor dies 202E to the second semiconductor die 201E and to electrically isolate the third inner connectors 240E from each other. Second, third and fourth level dies 202-2E, 202-3E, and 202-4E of the third semiconductor dies 202E sequentially stacked on the first level die 202-1E may also be bonded to each other by the third inner connectors 240E and the second adhesive layer 270E. The second semiconductor die 201E may be configured to include second through vias 221E, and the third semiconductor dies 202E may be configured to include third through vias 222E.

The second semiconductor die stack 200E may further include a side molding layer 350E. The side molding layer 350E may include an encapsulant material such as an EMC material. The side molding layer 350E may be disposed on the second semiconductor die 201E and may extend to surround and cover side surfaces 202S of the third semiconductor dies 202E. The side molding layer 350E may be disposed such that a top surface 202T of the fourth level die 202-4E corresponding to a topmost die of the third semiconductor dies 202E is exposed. Because the top surface 202T of the fourth level die 202-4E is left exposed by the side molding layer 350E, heat generated by the third semiconductor dies 202E may be more readily radiated from the exposed top surface 202T.

Referring again to FIG. 1, the semiconductor package 10 may further include a passivation layer 600. The passivation layer 600 may be located at an interface between the first semiconductor die 100 and the encapsulant layer 300. The passivation layer 600 may be disposed to electrically isolate and insulate the first semiconductor die 100 from the thermal conduction balls 401 dispersed in the encapsulant layer 300. The passivation layer 600 may extend into an interface between the second semiconductor die stack 200 and the encapsulant layer 300. The passivation layer 600 may extend to electrically isolate and insulate the second semiconductor die stack 200 from the thermal conduction balls 401 dispersed in the encapsulant layer 300.

The passivation layer 600 may include an insulation layer. For example, the passivation layer 600 may include a silicon nitride layer, a silicon oxide layer, a combination layer of a silicon nitride layer and a silicon oxide layer, or a polymer layer. For some embodiments, the silicon oxide layer or the silicon nitride layer used as the passivation layer 600 may be formed to have a thickness of at least 1 micrometer. For some embodiments, the polymer layer used as the passivation layer 600 may be formed to have a thickness of at least 5 micrometers using a spray process.

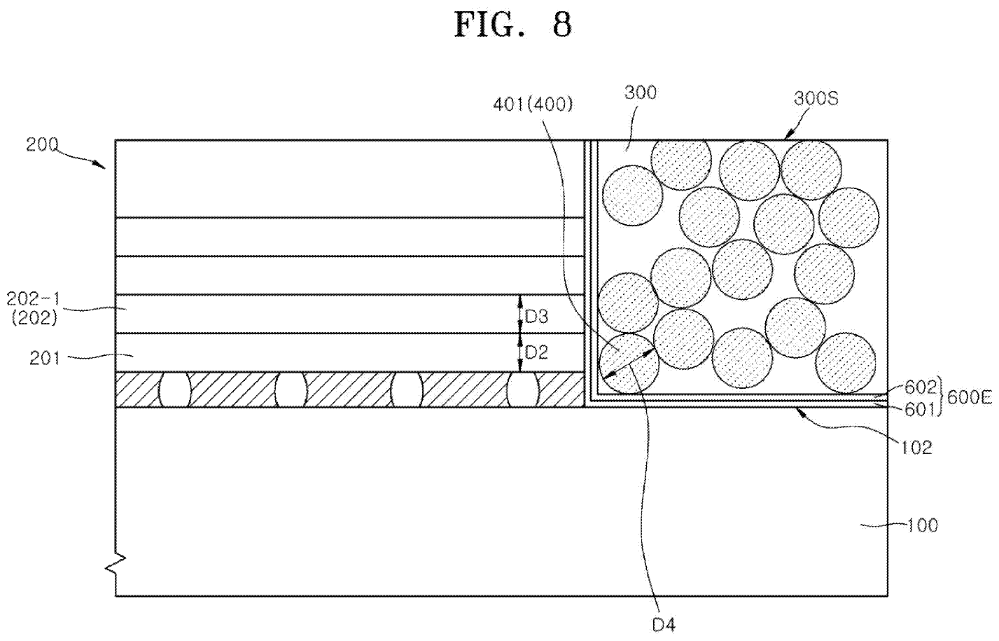

FIG. 8 is a cross-sectional view illustrating a passivation layer of a semiconductor package. The passivation layer 600E represents another embodiment of the passivation layer 600 shown in FIG. 1.

Referring to FIG. 8, the passivation layer 600E may be formed to include a thermal conduction layer 602. For example, the passivation layer 600E may include an insulation layer 601 covering edge portions of the first semiconductor die 100 and side surfaces of the second semiconductor die stack 200, and the thermal conduction layer 602 may be disposed on the insulation layer 601. The thermal conduction layer 602 may improve the thermal conduction of heat from the first 100, second 201, and third 202 semiconductor dies to the thermal conduction network structure 400. The thermal conduction layer 602 may include a silver paste layer or a metal layer. In some embodiments, the thermal conduction layer 602 may include a thermal conduction material such as a carbon nanotube layer or a graphene layer.

Referring again to FIG. 8, the thermal conduction balls 401 dispersed in the encapsulant layer 300 may have a diameter D4 which is greater than a thickness D2 of the second semiconductor die 201. The diameter D4 of the thermal conduction balls 401 may be greater than a thickness of at least one of the third semiconductor dies 202. For example, the diameter D4 of the thermal conduction balls 401 may be greater than a thickness D3 of the first level die 202-1 of the third semiconductor dies 202. In an embodiment, the diameter D4 of the thermal conduction balls 401 may be at least 100 micrometers. As described above, because the diameter D4 of the thermal conduction balls 401 has a relatively large value as compared to at least one of the second 201 and third 202 semiconductor dies, the number of the thermal conduction balls 401 constituting the thermal conduction network structure 400 disposed between a horizontal portion of the passivation layer 600E and the top surface 300S of the encapsulant layer 300 may be relatively reduced as compared to if the thermal conduction balls 401 had a smaller diameter. That is, because the diameter D4 of the thermal conduction balls 401 has a relatively large value, the heat generated by the first semiconductor die 100 and the second semiconductor die stack 200 may be more efficiently emitted through the thermal conduction network structure 400.

When the encapsulant layer 300 and the thermal conduction balls 401 constitute the entire portion of a protection layer, a volume ratio of the thermal conduction balls 401 to the protection layer may be at least 70% for some embodiments. This protection layer may correspond to a molding layer. As such, if the volume ratio of the thermal conduction balls 401 to the protection layer increases, the thermal conduction network structure 400 may be more readily realized. Accordingly, a thermal transmission effect of the thermal conduction network structure 400 may be improved.

Referring again to FIG. 1, the encapsulant layer 300 may be formed such that the top surface 202-4S of the fourth level die 202-4, corresponding to a topmost die of the third semiconductor dies 202, is left exposed. For example, the encapsulant layer 300 in which the thermal conduction balls 401 are dispersed may be formed to cover the second semiconductor die stack 200 and exposed portions of the first semiconductor die 100 not overlapped by the second semiconductor die stack 200. Subsequently, an upper portion of the encapsulant layer 300 may be removed using a back-grinding process. As a result of the back-grinding process, the top surface 202-4S of the fourth level die 202-4 may be exposed. If the top surface 202-4S of the fourth level die 202-4 is exposed, the heat generated by the third semiconductor dies 202 may be more readily dissipated from the top surface 202-4S of the fourth level die 202-4.

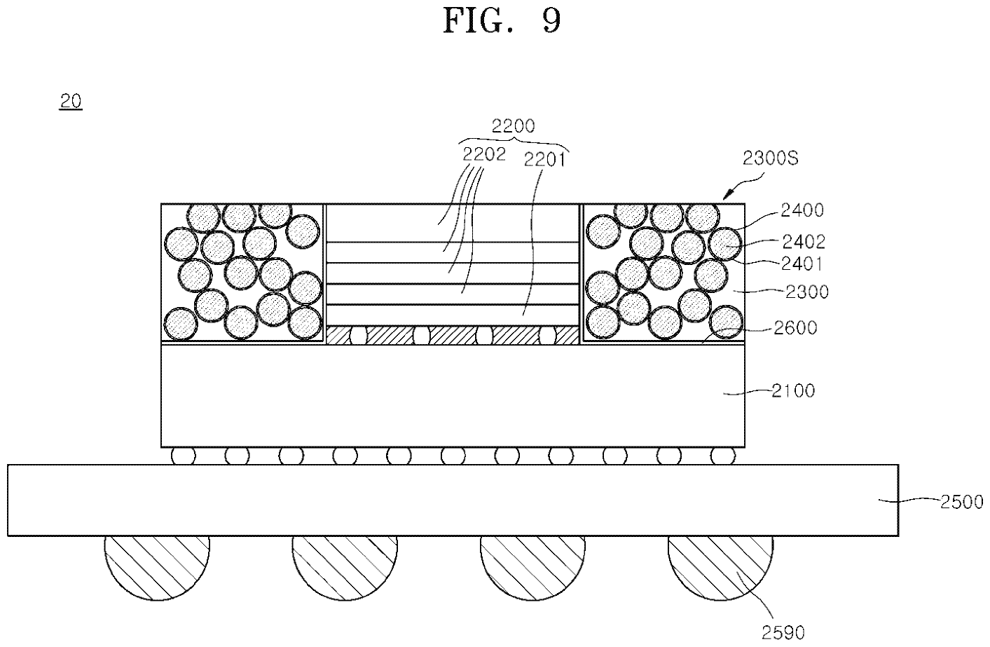

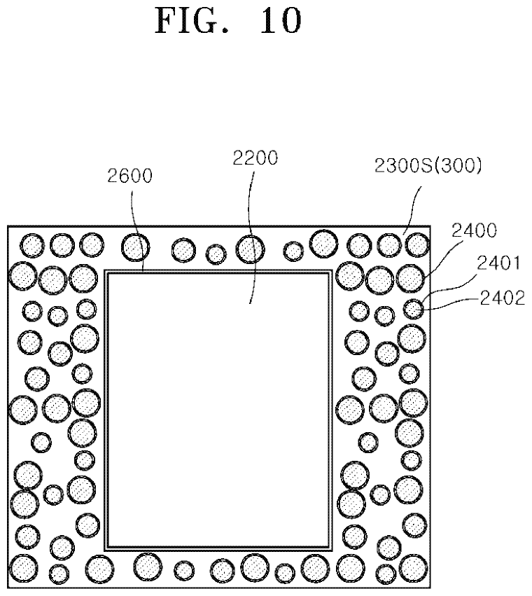

FIG. 9 is a cross-sectional view illustrating a semiconductor package 20 according to another embodiment. FIG. 10 is a plan view illustrating an encapsulant layer 2300 of the semiconductor package 20 shown in FIG. 9.

Referring to FIGS. 9 and 10, the semiconductor package 20 may be configured to include a first semiconductor die 2100, a second semiconductor die stack 2200, the encapsulant layer 2300, and a thermal conduction network structure 2400. A plurality of ball cores 2402, each with a thermal conduction coating layer 2401, may be dispersed in the encapsulant layer 2300. The thermal conduction network structure 2400, in particular, the thermal conduction coating layers 2401, may surround surfaces of the ball cores 2402 and may extend to connect the ball cores 2402 to each other. The thermal conduction network structure 2400 may extend from a surface portion of the first semiconductor die 2100 to a top surface 2300S of the encapsulant layer 2300. Some portions of the thermal conduction network structure 2400 may be exposed at the top surface 2300S of the encapsulant layer 2300.

The semiconductor package 20 may further include a package substrate 2500 on which the first semiconductor die 2100 is mounted. Outer connectors 2590 may be attached to a surface of the package substrate 2500 opposite to the first semiconductor die 2100.

The second semiconductor die stack 2200 may be vertically stacked on the first semiconductor die 2100. The second semiconductor die stack 2200 may include a plurality of semiconductor dies which are vertically stacked. For example, the second semiconductor die stack 2200 may be configured to include a second semiconductor die 2201 stacked on the first semiconductor die 2100 and a plurality of third semiconductor dies 2202 stacked on the second semiconductor die 2201. The second semiconductor die stack 2200 may be a high bandwidth memory (HBM) device. The second semiconductor die 2201 and the third semiconductor dies 2202 of the second semiconductor die stack 2200 may be stacked using the DBI technique described with reference to FIG. 6.

The semiconductor package 20 may further include a passivation layer 2600. The passivation layer 2600 may be located at an interface between the first semiconductor die 2100 and the encapsulant layer 2300. The passivation layer 2600 may be disposed to electrically isolate and insulate the first semiconductor die 2100 from the thermal conduction network structure 2400 in the encapsulant layer 2300. The passivation layer 2600 may extend into an interface between the second semiconductor die stack 2200 and the encapsulant layer 2300. The passivation layer 2600 may extend to electrically isolate and insulate the second semiconductor die stack 2200 from the thermal conduction network structure 2400 in the encapsulant layer 2300. The passivation layer 2600 may include an insulation layer, a thermal conduction layer, or a combination layer thereof, as described with reference to FIG. 8.

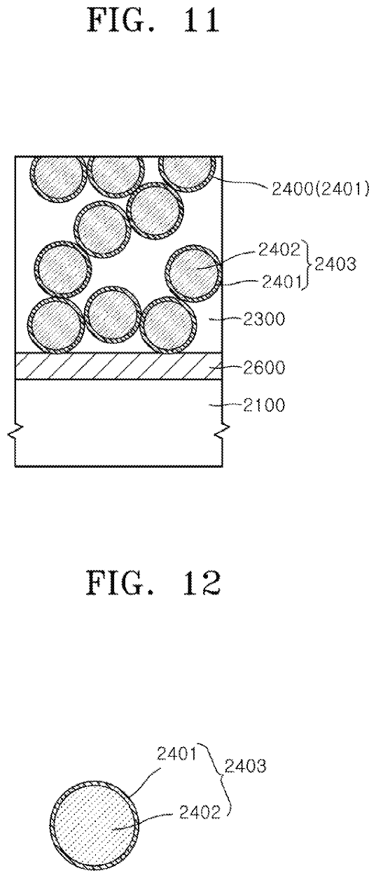

FIG. 11 is a cross-sectional view illustrating the thermal conduction network structure 2400 of the semiconductor package 20 shown in FIG. 9. FIG. 12 is a cross-sectional view illustrating the ball core 2402 constituting the thermal conduction network structure 2400 of FIG. 11.

Referring to FIG. 11, the thermal conduction network structure 2400 may be disposed to provide heat transmission paths in the encapsulant layer 2300. A plurality of thermal conduction balls 2403 may constitute the thermal conduction network structure 2400. Each of the thermal conduction balls 2403 may be configured to include the ball core 2402 and the thermal conduction coating layer 2401 coating a surface of the ball core 2402. The thermal conduction coating layer 2401 may include a solder layer for some embodiments. The solder layer used as the thermal conduction coating layer 2401 may include a solder layer having a low melting point. For example, the solder layer used as the thermal conduction coating layer 2401 may be formed of a tin-bismuth (Sn—Bi) type solder material or a tin-indium (Sn—In) type solder material.

The thermal conduction network structure 2400 may be formed by dispersing the thermal conduction balls 2403 in the encapsulant layer 2300 and by heating the thermal conduction balls 2403 in the encapsulant layer 2300 to melt the thermal conduction coating layer 2401. In such a case, the solder material of the thermal conduction coating layers 2401 may be melted to fuse or bond the ball cores 2402 to each other. As a result, the ball cores 2402 may be physically and thermally connected to each other, thereby providing the thermal conduction network structure 2400 having a branched shape in the encapsulant layer 2300.

Because the thermal conduction coating layers 2401 coating the ball cores 2402 are melted to form the thermal conduction network structure 2400, the ball cores 2402 may be formed of a material having a thermal conductivity which is lower than a thermal conductivity of the thermal conduction coating layers 2401. For example, the ball cores 2402 may be ceramic balls or polymeric balls. Additionally or alternatively, the ball cores 2402 may be formed of a material having a thermal conductivity which is higher than a thermal conductivity of the encapsulant layer 2300. For example, the ball cores 2402 may be formed to include copper, nickel, carbon nanotubes, stainless steel, or zinc.

As described with reference to FIG. 1 (or 9), the semiconductor package 10 (or 20) may include the thermal conduction network structure 400 (or 2400) providing heat transmission paths in the encapsulant layer 300 (or 2300). Thus, even though the second semiconductor die stack 200 (or 2200) is vertically stacked on the first semiconductor die 100 (or 2100), the heat generated by operations of the first semiconductor die 100 (or 2100) may be more readily conducted through the thermal conduction network structure 400 (or 2400). Accordingly, the thermal conduction network structure 400 (or 2400) may effectively suppress, reduce, or mitigate the deleterious and undesirable effects of a buildup of heat generated by the first semiconductor die 100 (or 2100). Even though the first semiconductor die 100 (or 2100) may generate more heat than the second semiconductor die stack 200 (or 2200), it may be possible to stack the second semiconductor die stack 200 (or 2200) on the first semiconductor die 100 (or 2100) without causing any degradation in performance of the second semiconductor die stack 200 (or 2200) because of the presence of the thermal conduction network structure 400 (or 2400).

As described above, and according to various embodiments, heat generated by a first semiconductor die may be more efficiently emitted through a thermal conduction network structure even though a second semiconductor die stack is stacked on the first semiconductor die.

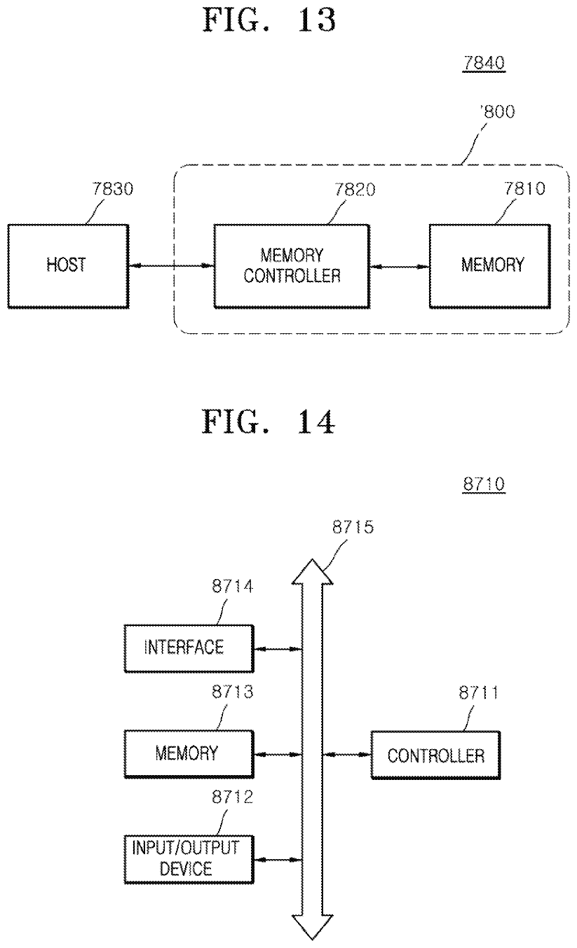

FIG. 13 is a block diagram illustrating an electronic system 7840 including a memory card 7800 employing at least one semiconductor package according to an embodiment of the present teachings. The memory card 7800 includes a memory 7810, such as a nonvolatile memory device, and a memory controller 7820. The memory 7810 and the memory controller 7820 may store data and/or read out stored data. At least one of the memory 7810 and the memory controller 7820 may include one or more semiconductor packages according to an embodiment of the present teachings.

The memory 7810 may include a nonvolatile memory device to which the teachings of the present disclosure are applied. The memory controller 7820 may control the memory 7810 such that stored data is read out or data is stored in response to a read/write request from a host 7830.

FIG. 14 is a block diagram illustrating an electronic system 8710 including at least one semiconductor package according to an embodiment of the present teachings. The electronic system 8710 may include a controller 8711, an input/output unit 8712, and a memory 8713. The controller 8711, the input/output unit 8712, and the memory 8713 may be coupled with one another by a bus 8715 providing a path through which data can move.

In an embodiment, the controller 8711 may include one or more of a microprocessor, a digital signal processor, a microcontroller, and/or may include a logic device capable of performing the same functions as such components. The controller 8711 and/or the memory 8713 may include one or more semiconductor packages according to embodiments of the present disclosure. The input/output unit 8712 may include at least one component selected from among a keypad, a keyboard, a display device, a touchscreen, and so forth. The memory 8713 is a device for storing data. The memory 8713 may store data and/or commands to be executed by the controller 8711, and the like.

The memory 8713 may include a volatile memory device, such as a DRAM, and/or a nonvolatile memory device, such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be of a wired or wireless type. For example, the interface 8714 may include a wired transceiver or a wireless transceiver with an antenna.

The electronic system 8710 may be realized as a mobile system, a personal computer, an industrial computer, or a logic system performing various functions. For example, the mobile system may be any one of a personal digital assistant (PDA), a portable computer, a tablet computer, a mobile phone, a smart phone, a wireless phone, a laptop computer, a memory card, a digital music system, and an information transmission/reception system.

When the electronic system 8710 represents equipment capable of performing wireless communication, the electronic system 8710 may be used in a communication system using a technique of CDMA (code division multiple access), GSM (global system for mobile communications), NADC (north American digital cellular), E-TDMA (enhanced-time division multiple access), WCDAM (wideband code division multiple access), CDMA2000, LTE (long term evolution), or Wibro (wireless broadband Internet).

A limited number of possible embodiments have been disclosed for illustrative and explanatory purposes. Those skilled in the art will appreciate that various modifications, additions, subtractions, and/or substitutions are possible without departing from the scope and spirit of the present disclosure and the accompanying claims.

What is claimed is:

1. A semiconductor package comprising:
a second semiconductor die stacked on a first semiconductor die;
an encapsulant layer disposed on the first semiconductor die and adjacent to the second semiconductor die; and
a thermal conduction network structure comprising a plurality of thermal conduction balls dispersed in the encapsulant layer.

2. The semiconductor package of claim 1,
wherein the plurality of thermal conduction balls of the thermal conduction network structure are in contact with each other; and
wherein the thermal conduction network structure comprises contiguous and continuous heat conduction paths through the plurality of contacting thermal conduction balls from a surface of the first semiconductor die to a surface of the encapsulant layer.

3. The semiconductor package of claim 1, wherein a portion of the plurality of thermal conduction balls are exposed at a surface of the encapsulant layer.

4. The semiconductor package of claim 1, wherein at least one of the plurality of thermal conduction balls comprises at least one of copper, nickel, a carbon nanotube, stainless steel, and zinc.

5. The semiconductor package of claim 1, further comprising a passivation layer disposed between the first semiconductor die and the encapsulant layer,
wherein the passivation layer extends into an interface between the second semiconductor die and the encapsulant layer.

6. The semiconductor package of claim 5, wherein the passivation layer comprises an insulation layer electrically isolating the first and second semiconductor dies from the plurality of thermal conduction balls.

7. The semiconductor package of claim 6, wherein the insulation layer comprises at least one of silicon nitride, silicon oxide, and polymer.

8. The semiconductor package of claim 5, wherein the passivation layer comprises a thermal conduction layer.

9. The semiconductor package of claim 8, wherein the thermal conduction layer comprises at least one of a silver paste layer, a metal layer, a carbon nanotube layer, and a graphene layer.

10. The semiconductor package of claim 1, further comprising third semiconductor dies stacked on the second semiconductor die.

11. The semiconductor package of claim 10, wherein the encapsulant layer is disposed such that a top surface of a topmost die of the third semiconductor dies is exposed.

12. The semiconductor package of claim 10, wherein a bottommost die of the third semiconductor dies is directly bonded to the second semiconductor die using a direct bonding interconnection (DBI) technique.

13. The semiconductor package of claim 10, wherein the plurality of thermal conduction balls has a diameter which is greater than a thickness of at least one of the second and third semiconductor dies.

14. The semiconductor package of claim 1, wherein the plurality of thermal conduction balls has a diameter of at least 100 micrometers.

15. The semiconductor package of claim 1, further comprising a package substrate on which the first semiconductor die is mounted,
wherein the first semiconductor die includes through silicon vias (TSVs) electrically connecting the second semiconductor die to the package substrate.

16. The semiconductor package of claim 15, further comprising:
first inner connectors electrically connecting the first semiconductor die to the package substrate; and
second inner connectors electrically connecting the second semiconductor die to the first semiconductor die.

17. The semiconductor package of claim 1, wherein the encapsulant layer disposed adjacent to the second semiconductor die comprises the encapsulant layer surrounding side surfaces of the second semiconductor die.

18. The semiconductor package of claim 1, wherein each of the plurality of thermal conduction balls dispersed in the encapsulant layer comprises a ball core surrounded by a thermal conduction coating layer.

19. A semiconductor package comprising:
a second semiconductor die stacked on a first semiconductor die;
an encapsulant layer disposed on the first semiconductor die to surround the second semiconductor die;
a plurality of ball cores dispersed in the encapsulant layer; and
a thermal conduction network structure surrounding surfaces of the plurality of ball cores and extending to connect the plurality of ball cores to each other.

20. The semiconductor package of claim 19,
wherein the thermal conduction network structure extends from a portion of a surface of the first semiconductor die to a surface of the encapsulant layer such that a portion of the thermal conduction network structure is exposed at the surface of the encapsulant layer; and
wherein the thermal conduction network structure forms continuous heat conduction paths from the portion of the surface of the first semiconductor die to the surface of the encapsulant layer.

21. The semiconductor package of claim 19, wherein the thermal conduction network structure comprises solder layers coating the surfaces of the ball cores and being fused together.

22. The semiconductor package of claim 19, wherein the plurality of ball cores comprises at least one of copper, nickel, a carbon nanotube, stainless steel, and zinc.

23. The semiconductor package of claim 19, wherein the plurality of ball cores comprises at least one of ceramic balls and polymer balls.
